(19) United States
(12) Patent Application Publication
(10) Pub. No.: US 2008/0073708 A1
(43) Pub. Date: Mar. 27, 2008

(54) SEMICONDUCTOR DEVICE AND METHOD OF FORMING THE SAME

(75) Inventor: Fumiki AISO, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/856,734

(22) Filed: Sep. 18, 2007

(30) Foreign Application Priority Data
Sep. 21, 2006 (JP) 2006-255746

(51) Int. Cl. H01L 29/78; H01L 21/336

(52) U.S. Cl. 257/334; 438/270; 257/E29.262; 257/E21.41

(57) ABSTRACT

A semiconductor device and a method of forming the semiconductor device are provided. The semiconductor device may include, but is not limited to, a semiconductor substrate and a third array of semiconductor elements. The semiconductor substrate may include a first array of separate grooves, a second array of separate active regions, and at least an isolating region, the isolating region separating the separate active regions from each other. Each separate groove extends in the separate active region and does not extend over the isolating region. The third array of semiconductor elements is provided on the semiconductor substrate. Each of the semiconductor elements has an electrically conductive portion that is provided in the separate groove. The semiconductor element may be a trench gate transistor, and the electrically conductive portion may be a gate electrode.

### BACKGROUND OF THE INVENTION

1. Field of the Invention

The present invention generally relates to a semiconductor device and a method of forming the same. More specifically, the present invention relates to a semiconductor device including a trench gate transistor, and a method of forming the same.

Priority is claimed on Japanese Patent Application No. 2006-255746, filed Sep. 21, 2006, the content of which is incorporated herein by reference.

2. Description of the Related Art

All patents, patent applications, patent publications, scientific articles, and the like, which will hereinafter be cited or identified in the present application, will hereby be incorporated by reference in their entirety in order to describe more fully the state of the art to which the present invention pertains.

A semiconductor memory device such as a dynamic random access memory (DRAM) includes a plurality of memory cells. Each memory cell includes a switching transistor and a capacitor. Shrinkage of the semiconductor device shrinks each MOS transistor included in the semiconductor device. Shrinkage of the MOS transistor makes the short channel effect more remarkable. In a large capacity DRAM, not only the memory cell is scaled down but also the channel length of a transfer gate transistor is reduced. Reduction of the channel length of a transfer gate transistor performing as a memory cell switching transistor can deteriorate the performances thereof. Deterioration of the performance of the transfer gate transistor can deteriorate retention and writing characteristics of DRAM memory cells. The transfer gate transistor will, hereinafter, be referred to as a memory cell transistor.

A trench gate transistor having a three-dimensional channel has been developed as one of the countermeasures to prevent the short channel effects. In the trench gate transistor, a semiconductor substrate has a groove. The groove has a three-dimensional interface that can be used as a three-dimensional channel. The three-dimensional channel has a longer channel length than the normal two-dimensional channel. The trench gate transistor is also called to as a recess channel access transistor. FIG. 15 is a fragmentary plan view illustrating a conventional memory cell array including trench gate transistors. FIG. 16 is a fragmentary cross sectional elevation view, taken along an A-A line of FIG. 15, illustrating the conventional memory cell array including trench gate transistors.

As shown in FIG. 15, a memory cell array 101 is such that two bits memory cells are disposed in each active region. The memory cell array 101 includes a two dimensional array of active regions 102 in X-direction and Y-direction. Each active region 102 is a slender region which extends along an oblique direction to X-direction and Y-direction. The oblique direction is parallel to a longitudinal direction of the active region 102. The active regions 102 are aligned in Y-direction at a constant pitch. The active regions 102 are also aligned in the oblique direction. The memory cell array 101 includes a modified matrix array of the active regions 102.

Each active region 102 includes a bit line contact and two substrate contacts 105. The bit line contact is positioned at the center of each active region 102. The two substrate contacts 105 are positioned at opposing ends of each active region 102. Capacitors are also provided at the opposing ends of each active region 102. The capacitors are not illustrated in the drawing. Each capacitor is connected to the memory cell transistor and to the substrate contact 105.

The memory cell array 101 includes a plurality of bit lines 106 which are aligned in Y-direction at a constant pitch. Each bit line 106 extends in X-direction non-straightly. The memory cell array 101 also includes a plurality of word lines 107 which are aligned in X-direction at a constant pitch. Each word line 107 extends in Y-direction straightly. Parts of each word line 107 perform as gate electrodes of the memory cell transistors. The memory cells are arrayed in a modified matrix, which are connected to the bit lines 106 and the word lines 107.

The memory cell array 101 includes epitaxial layers 103 that are selectively formed in the semiconductor substrate. The epitaxial layers 103 perform as source and drain regions of the memory cell transistors. The memory cell array 101 also includes LDD side walls 108 that are adjacent to side walls of the word lines 107.

As shown in FIG. 16, a trench isolation insulating film 110 is formed in the semiconductor substrate. Grooves 111 are formed in the semiconductor substrate. A gate oxide film 112 is formed on the surfaces of the grooves 111 and the semiconductor substrate. Gate electrodes 113 are formed on the gate oxide film 112. The gate electrodes 113 has lower and upper portions, wherein the lower portion is positioned within the groove 111, and the upper portion is positioned above the surface of the semiconductor substrate. First conductive films 114 are formed in the substrate contacts. The first conductive films 114 fill with lower portions of the substrate contacts.

A first diffusion layer 115 having a lower impurity concentration is formed in the semiconductor substrate. The first diffusion layer 115 of the lower impurity concentration is adjacent to the first conductive film 114. The first diffusion layer 115 of the lower impurity concentration is positioned directly under the first conductive film 114.

A second diffusion layer 116 having a higher impurity concentration is formed in the semiconductor substrate. The second diffusion layer 116 of the higher impurity concentration is adjacent to the other first conductive film 114. The second diffusion layer 116 of the higher impurity concentration is positioned directly under the other first conductive film 114. Insulating masks 117 are provided directly over the gate electrodes 113. Second conductive films 119 are formed in the substrate contacts. The second conductive films 119 fill with upper portions of the substrate contacts. The second conductive films 119 are positioned directly over the first conductive films 114. Side wall oxide films 120 are provided on side walls of the upper portions of the gate electrodes 113. LDD side walls 108 are also provided which are positioned between the side wall oxide films 120 and the first conductive films 114 and also between the insulating masks 117 and the second conductive films 119.

Japanese Unexamined Patent Application, First Publication, No. 2004-335866 discloses a conventional trench gate transistor. A drain region is formed over a semiconductor substrate. A channel region is formed over the drain region. A source region is formed over the channel region. A source electrode is electrically connected to the source region. A gate is disposed on a gate insulating film. A gate electrode is electrically connected to the gate. The gate electrode extends covering a surface portion. Examples of the shape of the trench gate are stripe-shape in plan view, octagonal meshed shape in plan view, and ladder shape in plan view.

Japanese Unexamined Patent Application, First Publication, No. 2002-231945 discloses another conventional trench gate power MOS field effect transistor. A gate electrode is formed in a trench, a surface of which is covered by a gate oxide film. After a trench is formed, hydrogen anneal is carried out to repair crystal defects that have been generated on the trench side walls and in the vicinity of the trench.

Japanese Unexamined Patent Application, First Publication, No. 2005-183976 discloses a conventional recess channel array transistor. A buffer insulating film and a mask layer are formed over a substrate. The mask layer and the buffer insulating film are selectively etched to form a pattern. The pattern is used as an etching mask to selectively etch the substrate, thereby forming a recess channel trench in the substrate.

FIG. 17 is a fragmentary plan view illustrating a part of the memory cell array shown in FIGS. 15 and 16, wherein a positional relationship among the grooves 111 of the trench gate transistor, the selective epitaxial layers 103, the substrate contacts 105, and the bit lines 106 is illustrated. The grooves 111 of the trench gate transistors extend in parallel to each other and in Y-direction. The grooves 111 are aligned in X-direction at a constant pitch. The selectively epitaxial layers 103 are positioned between adjacent two of the grooves 111.

The grooves 111 are formed as follows. FIG. 18 is a fragmentary cross sectional elevation view, taken along a B-B′ line of FIG. 17, illustrating the part of the memory cell array. A trench isolation film 110 is selectively formed in a semiconductor substrate 101 by shallow trench isolation (STI) method. A thermal oxidation film 131 is selectively formed on a surface of the semiconductor substrate 130. A silicon oxide film 132 is formed on the thermal oxidation film 131. The lamination of the thermal oxidation film 131 and the silicon oxide film 132 is pattered, thereby forming stacks of the thermal oxidation film 131 and the silicon oxide film 132. Silicon nitride side walls 133 are formed on side walls of the stacks of the thermal oxidation film 131 and the silicon oxide film 132. Grooves 111 are selectively formed by an anisotropic etching such as a reactive ion etching, wherein the thermal oxidation film 131, the silicon oxide film 132 and the silicon nitride side walls 133 are used as etching masks. The reactive ion etching forms not only the grooves 111 in the semiconductor substrate 130, while forming other grooves 111a in the trench isolation film 110. After the grooves 111 and 111a are formed, the silicon oxide film 132, the thermal oxidation film 131, and the silicon nitride side walls 133 are removed. Word lines are then formed, which cover or bury the grooves 111. Other layers and films are then formed in the known matters, thereby obtaining the structure of FIG. 16.

As shown in FIG. 18, the process for forming the grooves 111 in the semiconductor substrate 130 etches not only the semiconductor substrate 130 but also the trench isolation film 110, thereby forming not only the grooves 111 in the semiconductor substrate 130 but also the grooves 111a in the trench isolation film 110. The formation of the grooves 111a forms parasitic capacitance between the diffusion layers 115 and 116 and the grooves 111a.

The trench gate transistor allows shortening the gate length. Shortening the gate length may allow shrinkage of the circuits of the memory cell array. The DRAM having the trench gate transistors may improve refresh performance. The DRAM having the trench gate transistors may have parasitic capacitance that need increased current to writing operation, thereby increasing the power consumption. The grooves 111 extend over the array of the trench gate transistors. Other trench gate transistors than the needed transistor may have diffusion layers which are separated by the gate insulating film from the grooves 111 in which the word lines are formed. Namely, the word line has plural parasitic capacitances coupled with the diffusion layers of the trench gate transistors along which the word line extends or runs. The parasitic capacitances coupled to the word line can cause a delay of signal transmission through the word line.

As described above, the grooves 111a are formed in the trench isolation film 110. The grooves 111a may be then buried but incompletely, so that any void is formed at the bottom of the groove 111a. Such void is then exposed when the groove is further processed. For forming word lines, a conductive layer is formed in the groove with filling gaps such as a void and then the conductive film is selectively removed or patterned by a photo-lithography process, but the conductive film may reside in the void. The residual portion of the conductive film in the void may cause a short circuit formation between adjacent word lines.

In view of the above, it will be apparent to those skilled in the art from this disclosure that there exists a need for an improved semiconductor device and/or a method of forming the same. This invention addresses this need in the art as well as other needs, which will become apparent to those skilled in the art from this disclosure.

### SUMMARY OF THE INVENTION

Accordingly, it is a primary object of the present invention to provide a semiconductor device.

It is another object of the present invention to provide a semiconductor device including one or more trench gate transistors with a groove or grooves that increase the channel length, without increasing parasitic capacitance.

It is a further object of the present invention to provide a semiconductor device including one or more trench gate transistors with a groove or grooves that increase the channel length, wherein the semiconductor device can prevent any short circuit formation on the transistor circuit, even a filling gap is formed in a trench isolation film.

It is a still further object of the present invention to provide a method of forming a semiconductor device.

It is yet a further object of the present invention to provide a method of forming a semiconductor device including one or more trench gate transistors with a groove or grooves that increase the channel length, without increasing parasitic capacitance.

It is an additional object of the present invention to provide a method of forming a semiconductor device including one or more trench gate transistors with a groove or grooves that increase the channel length, wherein the semiconductor device can prevent any short circuit formation on the transistor circuit, even a filling gap is formed in a trench isolation film.

In accordance with a first aspect of the present invention, a semiconductor device may include, but is not limited to, a semiconductor substrate and a third array of semiconductor elements. The semiconductor substrate may include a first array of separate grooves, a second array of separate active regions, and at least an isolating region, the isolating region separating the separate active regions from each other. Each separate groove extends in the separate active region and does not extend over the isolating region. The third array of semiconductor elements is provided on the semiconductor substrate. Each of the semiconductor elements has an electrically conductive portion that is provided in the separate groove. In some cases, the semiconductor element may be a trench gate transistor, and the electrically conductive portion may be a gate electrode.

In some cases, the trench gate transistor may include, but is not limited to, a gate insulating film, the gate electrode, and source and drain regions. The gate insulating film may cover an inner wall of the separate groove. The gate electrode may be provided on the gate insulating film in the separate groove. The source and drain regions may be provided in the semiconductor substrate. The source and drain regions may be separated from each other by the separate groove.

The isolating region may typically be a trench isolation film. One or more trench gate transistors may be provided in each separate active region. The separate groove may be positioned corresponding to a channel region of each trench gate transistor.

The isolating region may include a trench isolation film. One or more trench gate transistors maybe provided in each separate active region. The separate groove may be limited only in an interposed region between source and drain regions of each trench gate transistor.

The isolating region may include a trench isolation film. The separate active regions may be separated by the trench isolation film. Each separate active region may have at least one trench gate transistor. The separate groove may be positioned corresponding to a channel region of each trench gate transistor. The separate groove does not overlap the trench isolation film at an intermediate position between the separate active regions.

The trench gate transistor has a shortened distance between the source and drain regions, thereby scaling down the trench gate transistor. The above-described semiconductor device can suppress variation in threshold voltage of the trench gate transistor, even variation in threshold voltage is caused by the short channel effects.

In the above-described semiconductor device, each separate groove is formed for forming the semiconductor element such as the trench gate transistor. Each separate groove extends within the channel region of the trench gate transistor, but does not extend over the isolation region such as the trench isolation film. No groove is formed in the other regions than the channel region. This can prevent any unnecessary parasitic capacitance that is coupled to a word line. The above-described semiconductor device can prevent any unnecessary parasitic capacitance that is coupled to a word line, even the trench gate transistor is provided. No parasitic capacitance causes no signal delay problem or no reduction of the operation speed of the semiconductor device.

No groove in the trench isolation causes no problem with any residue of conductive material in the trench isolation film. No residue of conductive material in the trench isolation film causes no possibility of forming any short circuit with the gate electrode or the word line. Forming separate grooves minimizes the process area, thereby reducing any residue generated in etching process.

In accordance with a second aspect of the present invention, a method of forming a semiconductor device may include, but is not limited to, the following processes. A semiconductor substrate may be prepared, which includes a first array of separate grooves, a second array of separate active regions, and at least an isolating region, the isolating region separating the separate active regions from each other. Each separate groove extends in the separate active region and does not extend over the isolating region. A third array of semiconductor elements may be formed on the semiconductor substrate. Each of the semiconductor elements may have an electrically conductive portion that is provided in the separate groove.

In some cases, the semiconductor element may typically be a trench gate transistor, and the electrically conductive portion may be a gate electrode.

Forming the trench gate transistor may include the following processes. A gate insulating film may be formed, which covers an inner wall of the separate groove. The gate electrode is formed on the gate insulating film in the separate groove. Source and drain regions are formed in the semiconductor substrate. The source and drain regions are separated from each other by the separate groove.

The isolating region may include a trench isolation film. One or more trench gate transistors may be formed in each separate active region. The separate groove may be formed at a position which corresponds to a channel region of each trench gate transistor.

The isolating region may include a trench isolation film. One or more trench gate transistors may be formed in each separate active region. The separate groove may be formed only in an interposed region between source and drain regions of each trench gate transistor.

The isolating region may typically be a trench isolation film. The separate active regions may be formed to be separated by the trench isolation film. Each separate active region may be formed to have at least one trench gate transistor. The separate groove may be formed at a position which corresponds to a channel region of each trench gate transistor. The separate groove may be formed, which does not overlap the trench isolation film at an intermediate position between the separate active regions.

In the above-described method of forming the semiconductor device, each separate groove is formed for forming the semiconductor element such as the trench gate transistor. Each separate groove is formed which extends within the channel region of the trench gate transistor, but does not extend over the isolation region such as the trench isolation film. No groove is formed in the other regions than the channel region. This can prevent any unnecessary parasitic capacitance that is coupled to a word line. The above-described semiconductor device can prevent any unnecessary parasitic capacitance that is coupled to a word line, even the trench gate transistor is provided. No parasitic capacitance causes no signal delay problem or no reduction of the operation speed of the semiconductor device.

No groove in the trench isolation causes no problem with any residue of conductive material in the trench isolation film. No residue of conductive material in the trench isolation film causes no possibility of forming any short circuit with the gate electrode or the word line. Forming separate grooves minimizes the process area, thereby reducing any residue generated in etching process.

The method may further include carrying out a baking process in a hydrogen atmosphere after the separate grooves are formed. The semiconductor substrate may typically be a silicon substrate. The baking process may be carried out to cause silicon atoms to move, thereby reducing surface-irregularly on the opening edge of each separate groove. Carrying out the baking process in the hydrogen atmosphere can prevent the above-described problems with the residue.

These and other objects, features, aspects, and advantages of the present invention will become apparent to those skilled in the art from the following detailed descriptions taken in conjunction with the accompanying drawings, illustrating the embodiments of the present invention.

### BRIEF DESCRIPTION OF THE DRAWINGS

Referring now to the attached drawings which form a part of this original disclosure:

FIG. 1 is a fragmentary plan view illustrating a semiconductor device in accordance with a first embodiment of the present invention;

FIG. 2 is a fragmentary cross sectional elevation view illustrating the semiconductor device, taken along a C-C′ line of FIG. 1;

FIG. 3 is a fragmentary plan view illustrating a peripheral circuit transistor in a DRAM;

FIG. 4 is a fragmentary cross sectional elevation view illustrating a semiconductor device in a step involved in a fabrication process thereof in accordance with the embodiment of the present invention;

FIG. 5 is a fragmentary cross sectional elevation view illustrating the semiconductor device in another step subsequent to the step shown in FIG. 4;

FIG. 6 is a fragmentary cross sectional elevation view illustrating the semiconductor device in another step subsequent to the step shown in FIG. 5;

FIG. 7 is a fragmentary cross sectional elevation view illustrating the semiconductor device in another step subsequent to the step shown in FIG. 6;

FIG. 8 is a fragmentary cross sectional elevation view illustrating the semiconductor device in another step subsequent to the step shown in FIG. 7;

FIG. 9 is a fragmentary cross sectional elevation view illustrating the semiconductor device in another step subsequent to the step shown in FIG. 8;

FIG. 10 is a fragmentary cross sectional elevation view illustrating the semiconductor device in another step subsequent to the step shown in FIG. 9;

FIG. 11 is a fragmentary cross sectional elevation view illustrating the semiconductor device in another step subsequent to the step shown in FIG. 10;

FIG. 12 is a fragmentary cross sectional elevation view illustrating the semiconductor device in another step subsequent to the step shown in FIG. 11;

FIG. 13 is a fragmentary cross sectional elevation view illustrating the semiconductor device in another step subsequent to the step shown in FIG. 12;

FIG. 14 is a fragmentary cross sectional elevation view illustrating the semiconductor device in another step subsequent to the step shown in FIG. 13;

FIG. 15 is a fragmentary plan view illustrating a conventional memory cell array including trench gate transistors;

FIG. 16 is a fragmentary cross sectional elevation view, taken along an A-A line of FIG. 5, illustrating the conventional memory cell array including trench gate transistors;

FIG. 17 is a fragmentary plan view illustrating a part of the memory cell array shown in FIGS. 15 and 16; and

FIG. 18 is a fragmentary cross sectional elevation view, taken along a B-B′ line of FIG. 17, illustrating the part of the memory cell array.

### DETAILED DESCRIPTION OF THE INVENTION

Selected embodiments of the present invention will now be described with reference to the drawings. It will be apparent to those skilled in the art from this disclosure that the following descriptions of the embodiments of the present invention are provided for illustration only and not for the purpose of limiting the invention as defined by the appended claims and their equivalents.

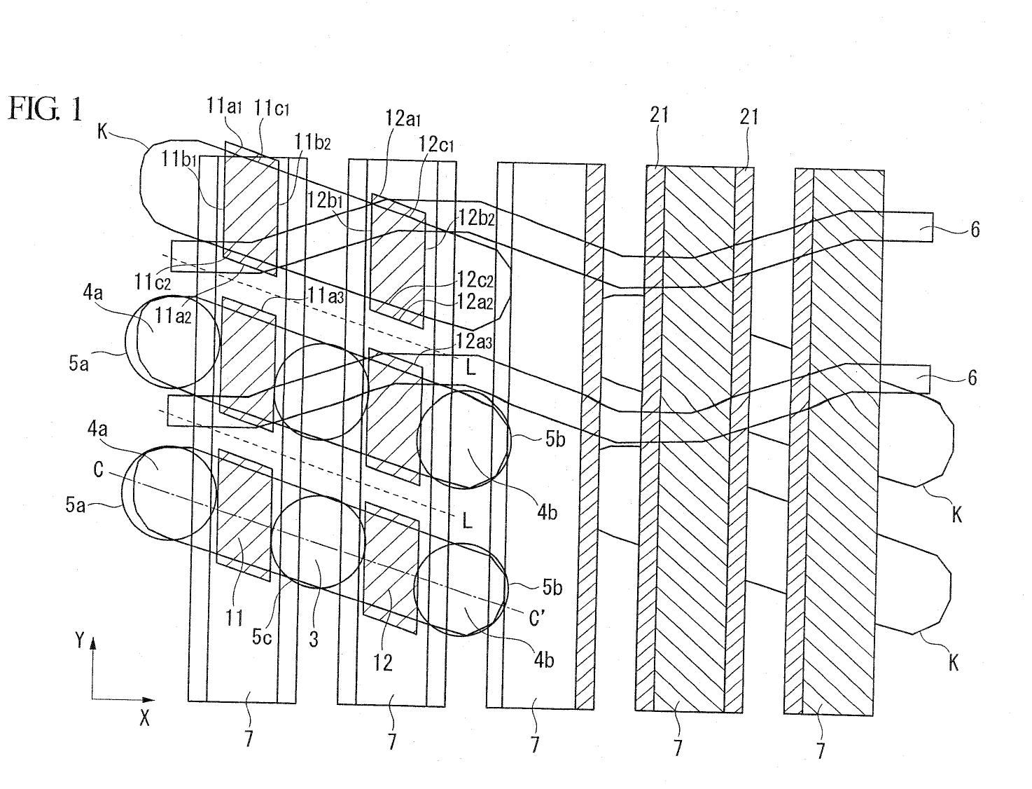

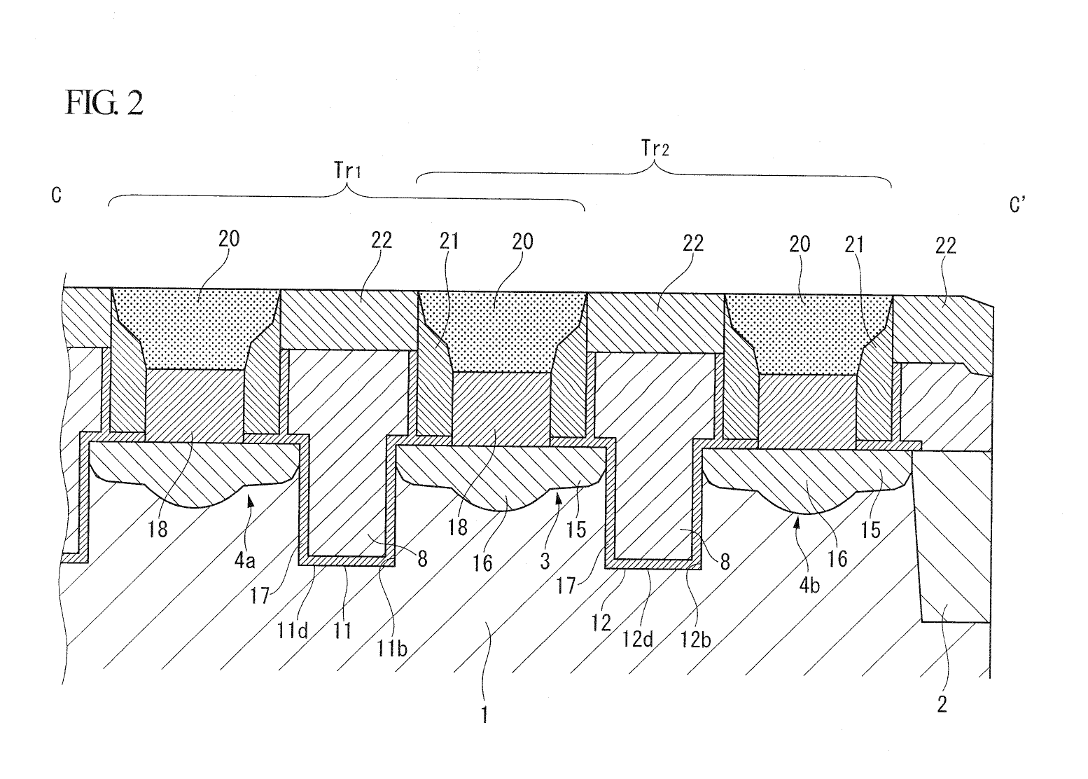

FIG. 1 is a fragmentary plan view illustrating a semiconductor device in accordance with a first embodiment of the present invention. FIG. 2 is a fragmentary cross sectional elevation view illustrating the semiconductor device, taken along a C-C′ line of FIG. 1.

The semiconductor device includes a semiconductor substrate 1, which may be made of a semiconductor such as silicon, having a predetermined impurity concentration. A trench isolation film 2 is electively formed in the surface of the semiconductor substrate 1. The trench isolation film 2 can be formed by shallow trench isolation method. The trench isolation film 2 covers other region than active regions K of the semiconductor substrate 1, so as to separate one active region K from other active region K adjacent to the one active region. In this embodiment, two bit memory cells may, for example, be disposed in each active region K.

As shown in FIG. 1, the semiconductor device includes a two-dimensional array of the active regions K. In some cases, the active regions K may be aligned in Y-direction at a constant pitch. The active regions K may also be aligned at a constant pitch in an oblique direction to X-direction. Each active region K may have a slender shape having a longitudinal direction that is parallel to the oblique direction. A first type diffusion layer 3 may selectively be disposed at the center of each active region K. Second type diffusion layers 4 may selectively be disposed at opposite sides of each active region K. The first type diffusion layer 3 may be a drain region, and the second type diffusion layers 4 may be source regions. Namely, the drain region 3 may be positioned at the center of each active region K, and the source regions 4a and 4b may be positioned at the opposing sides of each active region K. A first substrate contact 5a may be positioned directly over the source region 4a. A second substrate contact 5b may be positioned directly over the source region 4b. A third substrate contact 5c may be positioned directly over the drain region 3.

The shape and the longitudinal direction of each active region K as well as the array pattern and alignment directions should not be limited but can be modified as long as they are applicable to trench gate transistors.

A plurality of bit lines 6 are provided, which extend generally along X-direction. Each bit line 6 runs wavy and generally along X-direction. The plurality of bit lines 6 are parallel to each other and distanced at a contact pitch in Y-direction.

A plurality of word lines 7 are also provided, which extend along Y-direction. Each word line 7 runs straightly and along Y-direction. The plurality of word lines 7 are parallel to each other and distanced at a contact pitch in X-direction. Each word line 7 runs crossing over the plurality of active regions K. In other words, each word line 7 has a plurality of crossing portions which overlap the active regions K. The crossing portions act as gate electrodes 8 of trench gate transistors.

As shown in FIG. 2, first and second trench gate transistors Tr1 and Tr2 are provided in each active region K which is defined by the trench isolation film 2. In the semiconductor substrate 1, each active region K is defined by the trench isolation film 2. In each active region K, the two source regions 4a and 4b and the drain region 3 are formed separately from each other. The drain region 3 is interposed between the two source regions 4a and 4b. A first groove 11 is provided in the semiconductor substrate 1, wherein the first groove 11 separates the drain region 3 from the source region 4a. A second groove 12 is provided in the semiconductor substrate 1, wherein the second groove 12 separates the drain region 3 from the source region 4b. In other words, the first groove 11 is interposed between the drain region 3 and the source region 4a. The second groove 12 is interposed between the drain region 3 and the source region 4b.

As described above, the word lines 7 continuously run in Y-direction. The first and second grooves 11 and 12 discontinuously extend along the word lines 7 in Y-direction. Each of the first and second grooves 11 and 12 extends across the active region K, and is interposed between the drain region 3 and the source region 4a or 4b. The first grooves 11 are discontinuously aligned in Y-direction and along the word line 7. The second grooves 11 are also discontinuously aligned in Y-direction and along the word line 7 which is adjacent to the word line 7, along which the first grooves 11 are discontinuously aligned. Each of the first and second grooves 11 and 12 has a three-dimensional channel region of the trench gate transistor Tr in the active region K. The three-dimensional channel region is defined by the groove 11 or 12. The three-dimensional channel region between the source region 4a and the drain region 3 is defined by the first groove 11. The three-dimensional channel region between the source region 4b and the drain region 3 is defined by the second groove 12. Adjacent two of the first grooves 11 which are aligned discontinuously along the word line 7 are separated by the trench isolation film 2. Adjacent two of the second grooves 12 which are aligned discontinuously along the word line 7 are also separated by the trench isolation film 2. In Y-direction, the first grooves 11 are separate for each active region K. In Y-direction, the second grooves 12 are also separate for each active region K.

In some cases, the groove 11 may be defined by a first pair of inner walls 11a1 and 11a2, a second pair of inner walls 11b1 and 11b2, and a bottom wall 11d. The first-paired inner walls 11a1 and 11a2 are positioned outside side edges 11c1 and 11c2 of each active region K. The first-paired inner walls 11a1 and 11a2 may be distanced from each other in Y-direction. The first-paired inner walls 11a1 and 11a2 may be parallel to each other. The first-paired inner walls 11a1 and 11a2 may extend in the oblique direction, namely may be parallel to the longitudinal direction of each active region K. The second-paired inner walls 11b1 and 11b2 may be distanced from each other in X-direction. The second-paired inner walls 11b1 and 11b2 may be parallel to each other. The second-paired inner walls 11b1 and 11b2 may extend in Y-direction, namely may be parallel to the longitudinal direction of each word line 7. The first-paired inner walls 11a1 and 11a2 are adjacent to the second-paired inner walls 11b1 and 11b2. The first-paired inner walls 11a1 and 11a2 and the second-paired inner walls 11b1 and 11b2 are adjacent to the bottom wall 11d. The groove 11 may be regarded as a single trench groove.

In some cases, the groove 12 may be defined by a first pair of inner walls 12a1 and 12a2, a second pair of inner walls 12b1 and 12b2, and a bottom wall 12d. The first-paired inner walls 12a1 and 12a2 are positioned outside side edges 12c1 and 12c2 of each active region K. The first-paired inner walls 12a1 and 12a2 may be distanced from each other in Y-direction. The first-paired inner walls 12a1 and 12a2 may be parallel to each other. The first-paired inner walls 12a1 and 12a2 may extend in the oblique direction, namely may be parallel to the longitudinal direction of each active region K. The second-paired inner walls 12b1 and 12b2 may be distanced from each other in X-direction. The second-paired inner walls 12b1 and 12b2 may be parallel to each other. The second-paired inner walls 12b1 and 12b2 may extend in Y-direction, namely may be parallel to the longitudinal direction of each word line 7. The first-paired inner walls 12a1 and 12a2 are adjacent to the second-paired inner walls 12b1 and 12b2. The first-paired inner walls 12a1 and 12a2 and the second-paired inner walls 12b1 and 12b2 are adjacent to the bottom wall 12d. The groove 12 may be regarded as a single trench groove. The groove 11 may have a parallelogram shape in plan view.

Broken lines L represent positions at which filling gaps are likely to be formed in the trench isolation film 2. Each broken lines L run over intermediate points between two adjacent active regions K. In order to prevent the filling gaps from appearing on the grooves 11, it is necessary that the first-pared inner walls 11a1, 11a2, 11a3, 12a1, 12a2, and 12a3 do not overlap the broken lines L. In other words, the first-pared inner walls 11a1, 11a2, 11a3, 12a1, 12a2, and 12a3 can be modified in position as long as they are positioned outside the active regions and they do not overlap the broken lines L.

In this trench gate transistor Tr, the shape of each groove 11 or the positions of the inner walls of each groove 11 may be modified depending upon relative positions of the drain region 3 and the source regions 4a and 4b and upon the shape of the channel. The shape in plan view of each groove 11 can be modified depending upon the shape of the trench gate transistor Tr. The inner walls of each groove 11 may be either flat walls or curved walls. Examples of the shape in plan view of each groove 11 may include, but are not limited to, parallelogram, rectangle, circle, oval, and modified shapes thereof.

Each of the drain region 3 and the source regions 4a and 4b includes a first diffusion region 15 and a second diffusion region 16. The first diffusion region 15 is lower in impurity concentration than the second diffusion region 16. The first diffusion region 15 surrounds the second diffusion region 16. The first diffusion region 15 extends outside the second diffusion region 16. The second diffusion region 16 is surrounded by the first diffusion region 15. In other words, each of the drain region 3 and the source regions 4a and 4b includes center and side regions, wherein the center region is the second diffusion region 16 having the higher impurity concentration, and the side region is the first diffusion region 15 having the lower impurity concentration.

A gate insulating film 17 is formed which covers the bottom and side walls of each groove 11 as well as which extends over the top surface of the first diffusion regions 15. A gate electrode 8 is provided on the gate insulating film 17. The gate electrode 8 has a lower portion and an upper portion. The lower portion of the gate electrode 8 fills up the groove 11 and contacts with the gate insulating film 17. The upper portion of the gate electrode 8 projects upwardly from the lower portion thereof. The upper portion of the gate electrode 8 is positioned above the top surfaces of the drain region 3, and the source region 4a or 4b.

An insulating hard mask 22 is provided on the top surface of each gate electrode 8. The gate insulating film 17 separates the gate electrode 8 from the semiconductor substrate 1, the drain region 3, and the source region 4a or 4b. The upper portion of the gate electrode 8 is a part of the word line 7.

First conductors 18 are provided on the drain region 3, and the source regions 4a and 4b. Namely, the first conductors 18 contact with the upper surfaces of the drain region 3 and the source regions 4a and 4b. Second conductors 20 are provided over the first conductors 18. A first pair of the first and second conductors 18 and 20 that contact with the source region 4a constitutes a first substrate contact 5a. A second pair of the first and second conductors 18 and 20 that contact with the source region 4b constitutes a second substrate contact 5b. A third pair of the first and second conductors 18 and 20 that contact with the drain region 3 constitutes a third substrate contact 5c. The substrate contacts 5a, 5b and 5c are connected to capacitors that are not illustrated in FIGS. 1 and 2. Lightly doped side walls 21 are provided on side walls of each pair of the gate electrode 8 and the insulating hard mask 22.

A first trench gate transistor Tr1 is constituted by the gate insulating film 17 and the gate electrode 8 in the groove 11 and also by the source region 4a and the drain region 3. A second trench gate transistor Tr2 is constituted by the gate insulating film 17 and the gate electrode 8 in the groove 12 and also by the source region 4b and the drain region 3. A pair of the first and second trench gate transistors Tr1 and Tr2 is formed in each active region K. The semiconductor device has a two-dimensional array of active regions K, each of which includes a pair of the first and second trench gate transistors Tr1 and Tr2. Namely, the semiconductor device has a two-dimensional array of pairs of the first and second trench gate transistors Tr1 and Tr2. The paired first and second trench gate transistors Tr1 and Tr2 perform as selecting transistors for a memory cell.

In some cases, the gate insulating film 17 may be a silicon oxide film that is formed by a thermal oxidation of silicon. The gate electrode 8 may be a single-layered structure of polycrystalline silicon or a multi-layered structure of a polycrystalline silicon film and one or more metal films. The side walls 21 may be an insulating film such as a silicon nitride film.

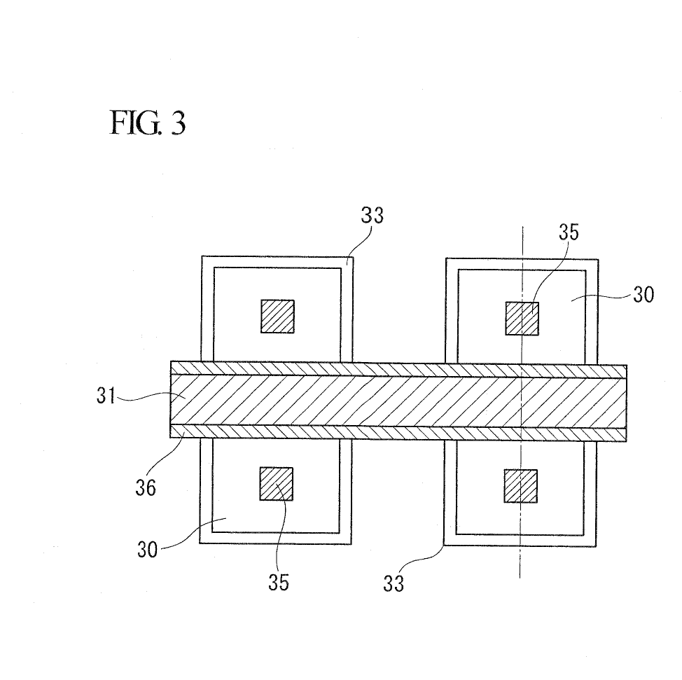

FIG. 3 is a fragmentary plan view illustrating a peripheral circuit transistor in a DRAM. The peripheral circuit transistors are formed in active regions 30. A word line 31 runs across the active regions 30. The active region 30 has a channel region which is positioned under the word line 31, and source and drain regions. The source and drain regions are separated by the channel region. The source and drain regions are diffusion regions. Selective epitaxial layers 33 are deposited on the diffusion regions. Substrate contacts 35 are formed over the selective epitaxial layers 33. LDD side walls 36 are formed on side walls of the word line 31. The memory cell area has trench gate transistors as described above. The peripheral circuit transistors may be either the trench gate transistors or planer transistors.

The trench gate transistor can be scaled down such as to shorten the distance between the drain region 3 and the source region 4a or 4b. If such trench gate transistor with shortened distances between the drain region 3 and the source region 4a or 4b has the above-described structure, then the trench gate transistor can prevent variation of threshold voltage Vt due to short channel effects.

The grooves 11 and 12 are formed in the active region K, such that the grooves 11 and 12 are separated from each other. This structure can prevent any groove from being formed in the trench isolation film. No groove in the trench isolation film causes no parasitic capacitance between the active region K and any position in the trench isolation film. The trench gate transistor free of any groove in the trench isolation film is significantly lower in parasitic capacitance with the word line than the trench gate transistor with a groove in the trench isolation film. In other words, no groove in the trench isolation film reduces parasitic capacitance with a word line. It is generally estimated that the trench gate transistor with a continuous groove outside the active region is higher by 1.8 times in parasitic capacitance than the normal gate transistor. The trench gate transistor free of any groove outside the active region is higher by 1.4 times in parasitic capacitance than the normal gate transistor.

The conventional trench gate transistor has at least a groove continuously extending outside the active region. The above-described trench gate transistor has one or more limited grooves such as grooves 11 and 12 that extend only in the channel region in the active region K. The grooves can be formed in the active region, while no groove is formed outside the active region. No groove formation in the trench isolation film can prevent generation of any additional parasitic capacitance coupled with the word line 7. If the groove extends outside the active region, any conductive material in the groove outside the active region produces an equivalent structure to the structure that active regions of the transistors are separated from each other but are adjacent to each other, thereby producing parasitic capacitance between the diffusion region and the word line.

The trench isolation film 2 can be formed in the semiconductor substrate 1 by shallow trench isolation. For example, a groove is formed in the semiconductor substrate 1. An insulating film is formed which fills the groove, thereby forming a trench isolation film 2. It is possible that the insulating film does not completely fill the groove, thereby forming any filling gap such as a void or voids. The trench gate transistor has any filling gap in the trench isolation film 2, and the groove extends outside the active region. In the formation of the gate electrode or the word line, a conductive material can be formed in the filling gap. The conductive material resides in the filling gap. The residual conductive material can form a short circuit when the wiring is formed. The above-described semiconductor device has the grooves 11 and 12 that are not present in the trench isolation film 2. No short circuit is formed.

When the grooves 11 and 12 are formed by etching process, any residue such as burr may be produced at the side edges 11c1 and 11c2 of the active region in the groove 11 and at the side edges 12c1 and 12c2 of the active region in the groove 12. However, the irregularity of such residual as burr can be removed or reduced by a baking process at a high temperature in a hydrogen atmosphere. If the semiconductor substrate 1 is a silicon substrate, the baking process at a high temperature in a hydrogen atmosphere cause diffusion of silicon atoms on surface thereby reducing the irregularity of such residual as burr. The baking process will be described later.

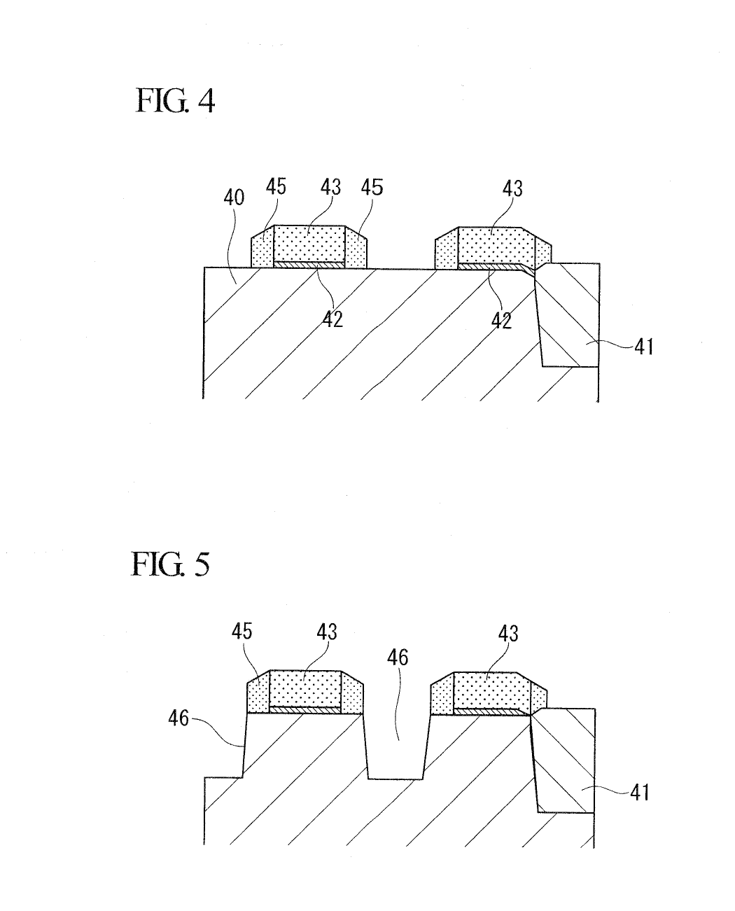

FIGS. 4 through 14 are fragmentary cross sectional elevation views illustrating semiconductor devices in sequential steps involved in a fabrication process thereof in accordance with the embodiment of the present invention.

As shown in FIG. 4, a trench isolation film 41 is formed in a silicon substrate 40 by shallow trench isolation, thereby defining active regions which are separate from each other. A thermal oxide film is formed on the surface of the silicon substrate 40 by a thermal oxidation process at a temperature in the range of about 750° C. through about 1100° C. A silicon nitride film is formed on the thermal oxide film by a chemical vapor deposition method (CVD method). The laminations of the thermal oxide film and the silicon nitride film is then selectively removed or patterned, thereby forming stack patterns of a thermal oxide film 42 and a silicon nitride film 43.

A silicon nitride film is formed by a chemical vapor deposition. The silicon nitride film covers the stack patterns of the thermal oxide film 42 and the silicon nitride film 43 as well as covers the surface of the silicon substrate 40. The silicon nitride film is then subjected to an anisotropic dry etching process, thereby forming side walls 45 on side walls of the stack patterns of the thermal oxide film 42 and the silicon nitride film 43. The anisotropic dry etching process can be carried out by a reactive ion etching process.

As shown in FIG. 5, the silicon substrate 40 has an exposed surface which is not covered by the stack patterns and the side walls 45 and which is not cover by the trench isolation film 41. Only the exposed surface of the silicon substrate 40 is subjected to an anisotropic dry etching process, thereby forming separate grooves 46 which will form three-dimensional channel regions. The separate grooves 46 do not extend to the trench isolation film 41. Namely, the trench isolation film 41 is free of any groove.

The separate grooves 46 will form three-dimensional channel regions in the active regions which are arrayed two-dimensionally. Namely, the three-dimensional channel regions are limited within the active regions, but do not extend outside the active regions. The separate grooves 46 are positioned between predetermined areas in which source and drain regions will be formed. The separate grooves 46 are defined by the side walls 45.

In this embodiment, the side walls 45 are formed on side walls of the stack patterns of the thermal oxide film 42 and the silicon nitride film 43. It is possible as a modification that no side walls are formed, and the separate grooves 46 are defined by the stack patterns of the thermal oxide film 42 and the silicon nitride film 43.

In some cases, a baking process can be carried out at a high temperature in a hydrogen atmosphere after the separate grooves 46 are formed. The baking process can be carried out under the following conditions but not limited thereto. For example, a hydrogen anneal process can be carried out at a temperature in the range of 950° C. to 1050° C., for a time period of 1 minute to 10 minutes, under a pressure of 10 mTorr to 760 mTorr, and in a hydrogen atmosphere having a hydrogen partial pressure of 1000 ppm to 100%.

The baking process at the high temperature in the hydrogen atmosphere causes surface diffusion of silicon atom. The surface diffusion of silicon atom rounds the corners of residues such as burr, and reduces or removes the projections thereof, even when the residues such as burr are once generated on the side walls of the grooves 46. The side walls of the grooves 46 correspond to the side edges 11c1, 11c2, 12c1, and 12c2 of each active region K. In other words, the baking process at the high temperature in the hydrogen atmosphere shapes the side walls of the grooves 46, thereby increasing the flatness and smoothness of the side walls thereof, and also reducing the surface irregularly of the side walls thereof, as well as reducing variation in shape of the grooves 46. This can prevent the short circuit formation and discontinuous film formation.

The separate grooves 46 are formed by removing the exposed surfaces of the silicon substrate 40, but not removing the trench isolation film 41. The trench isolation film 41 has no groove or recessed portion. It is assumed, however, that continuous grooves are formed which extend to the trench isolation film 41, thereby increasing parasitic capacitance as described above. The separate grooves 46 do not extend to the trench isolation film 41, thereby causing no problem with increasing parasitic capacitance.

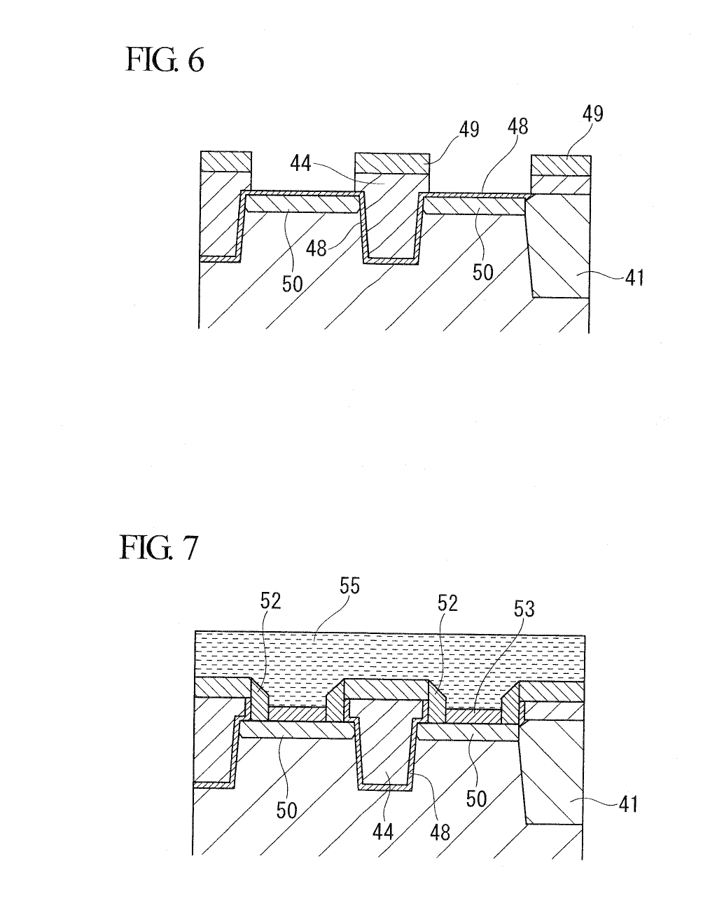

As shown in FIG. 6, the silicon nitride films 43 and the side alls 45, which have been used as masks for having formed the grooves 46, are removed by a phosphoric acid solution at a temperature in the range of 100° C. to 200° C. After the silicon nitride films 43 and the side alls 45 have been removed, the thermal oxide films 42 are exposed. The thermal oxide films 42 are then removed by a hydrofluoric acid solution. A preliminary treatment is carried out using acid and alkali solutions. A thermal oxidation of silicon is carried out at a temperature in the range of 750° C. to 1100° C., thereby forming a thermal oxide film of a thickness of not more than 10 nanometers. The thermal oxide film is then removed by a hydrofluoric acid solution. A further preliminary treatment is carried out using acid and alkali solutions. A further thermal oxidation of silicon is carried out at a temperature in the range of 750° C. to 1100° C., thereby forming a gate oxide film 48. A chemical vapor deposition process is carried out at a temperature in the range of about 500° C. to about 600° C., thereby forming a gate conductive film 44 on the gate oxide film 48. The gate conductive film 44 is an impurity doped silicon film. An insulating hard mask 49 is formed on the gate conductive film 44. The insulating hard mask 49 covers a predetermined region of the gate conductive film 44. A resist pattern is formed on the insulating hard mask 49. An anisotropic dry etching process is carried out using the resist pattern as a mask to selectively etch the insulating hard mask 49 and the gate conductive film 44 sequentially, thereby forming a stack of the insulating hard mask 49 and the gate conductive film 44. The resist pattern is removed.

An ion-implantation process is carried out using the insulating hard mask 49 and the gate conductive film 44 as masks to selectively introduce an impurity into the silicon substrate 40 through the gate oxide film 48 at a dose in the range of about 1E12 cm⁻² to 5E14 cm⁻². An anneal process is then carried out at a temperature in the range of 900° C. to 1100° C. so as to activate impurity diffusion regions of the silicon substrate 40, thereby forming diffusion layers 50 of a lower impurity concentration.

As shown in FIG. 7, LDD side walls 52 are formed on side walls of the stack of the insulating hard mask 49 and the gate conductive film 44. The LDD side walls 52 may be silicon nitride films. The gate oxide film 48 is selectively removed so that the diffusion layers 50 are exposed between the LDD side walls 52 and the trench isolation film 41. A selective epitaxial process is carried out to form silicon layers 53 on the exposed surfaces of the diffusion layers 50. A chemical vapor deposition process is carried out to form an interlayer insulator 55 which covers the silicon layers 53, the LDD side walls 52, and the insulating hard mask 49. The interlayer insulator 55 may be a boron-phosphorous-silicate-glass (BPSG) film which is a silicon oxide film doped with boron (B) and phosphorus (P). A heat treatment is then carried out to fluidize the BPSG film, thereby planarizing the BPSG film. In addition, a chemical mechanical polishing process is carried out to further planarize the BPSG film. A resist pattern is formed on the BPSG film. An anisotropic dry etching process is carried out using the resist pattern as a mask to form contact holes 56 in the BPSG film and over the selective epitaxial silicon layers 53. The selective epitaxial silicon layers 53 have exposed surfaces under the contact holes 56. The anisotropic dry etching process can be realized by a reactive ion etching process. The resist pattern is then removed.

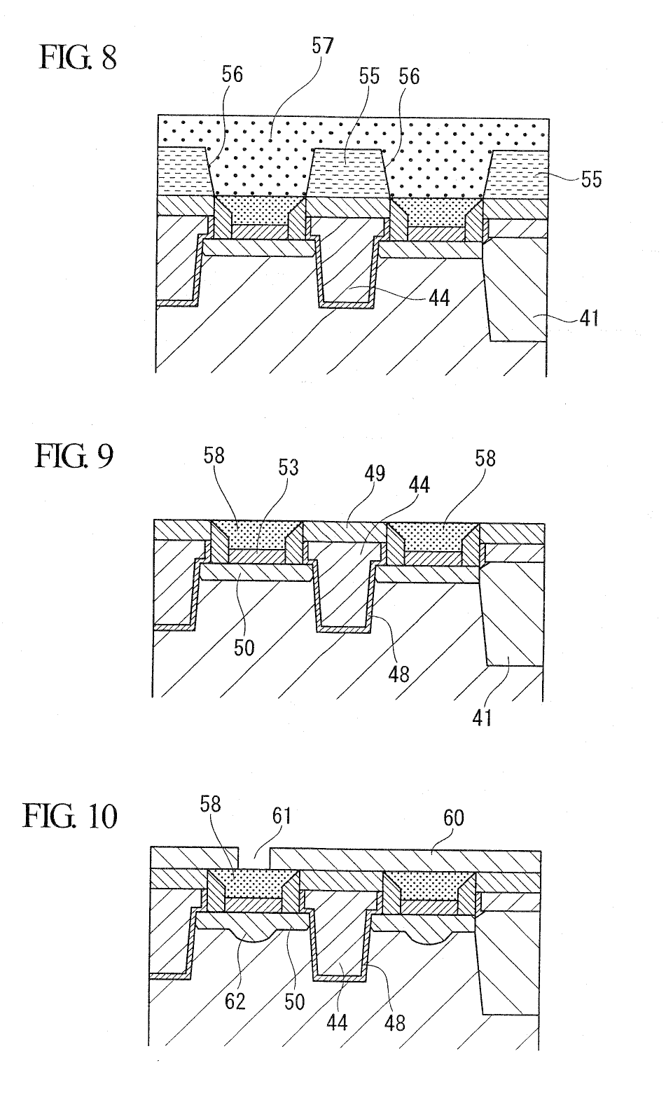

As shown in FIG. 8, a conductive film 57 is formed, which covers the interlayer insulator 55 and also covers the exposed surfaces of the selective epitaxial silicon layers 53 that are positioned under the contact holes 56. The conductive film 57 may be a silicon film that is doped with an n-type impurity. Namely, the conductive film 57 contacts with the exposed surfaces of the selective epitaxial silicon layers 53 that are positioned under the contact holes 56.

As shown in FIG. 9, the conductive film 57 is etched back so as to selectively leave the conductive film 57 only within the contact holes 56, thereby defining contact plugs 58 as the remaining portions of the conductive films 57 in the contact holes 56. The etching back process is carried out by an anisotropic dry etching process, a chemical mechanical polishing process, or a combination thereof. The anisotropic dry etching process can be realized by a reactive ion etching process. The top surfaces of the contact plugs 58 are leveled to the top surfaces of the insulating hard mask 49.

As shown in FIG. 10, a chemical vapor deposition process is carried out to form an interlayer insulator 60 of silicon oxide over the contact plugs 58 and the insulating hard mask 49. An anisotropic dry etching process is carried out to form a bit line contact hole 61 in the interlayer insulator 60 so that the contact plug 58 has an exposed surface under the contact hole 61. The anisotropic dry etching process can be realized by a reactive ion etching process. An impurity diffusion process is carried out to diffuse impurity in the contact plug 58 into the silicon substrate 40, thereby forming diffusion layers 60 of a higher impurity concentration. As a result, the source and drain regions are defined, each of which is a combination of the diffusion layers 50 and 60.

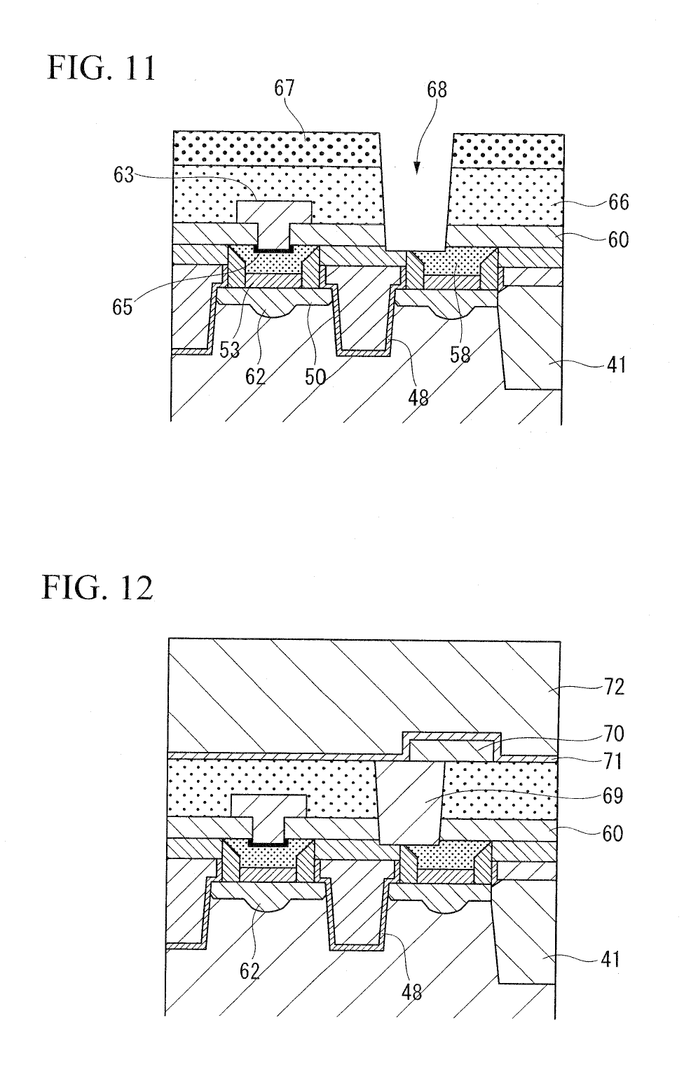

As shown in FIG. 11, a metal interconnect 63 is formed which extends within the bit line contact hole 61 and also over the interlayer insulator 60. In some cases, the metal interconnect 63 may be connected indirectly via a metal silicide film 65 to the contact plug 58. In other cases, the metal interconnect 63 may be connected directly to the contact plug 58. The metal interconnect 63 performs as a bit line. In some cases, the metal interconnect 63 may be made of W, Ti, or TiN. In some cases, the metal silicide film 65 may be formed on an interface between the metal interconnect 63 and the contact plug 58. The metal silicide film 65 may be made of cobalt silicide, titanium silicide, or tungsten silicide. The metal silicide film 65 can be formed by a silicidation reaction between silicon of the contact plug 58 and a metal of the metal interconnect 63.

A chemical vapor deposition process is carried out to form an interlayer insulator 66 which covers the metal interconnect 63 and the interlayer insulator 60. In some cases, the interlayer insulator 66 may be a silicon nitride film, a silicon oxide film, or a stack thereof. A chemical mechanical polishing process is carried out to planarize the interlayer insulator 66.

A resist pattern 67 is formed over the interlayer insulator 66. An anisotropic dry etching process is carried out using the resist pattern 67 as a mask, to selectively etch the interlayer insulators 66 and 60, thereby forming a contact hole 68. The anisotropic dry etching process can be realized by a reactive ion etching process. The contact hole 68 reaches a part of the contact plug 58 which is different from the contact plug 58 to which the metal interconnect 63 is connected. The contact hole 68 may also reach a part of the insulating hard mask 49. Namely, the contact hole 68 may reach both the contact plug 58 and the insulating hard mask 49.

As shown in FIG. 12, a conductive plug 69 is formed within the contact hole 68 so that the conductive plug 69 contacts with both the contact plug 58 and the insulating hard mask 49. The conductive plug 69 may be formed of an impurity-doped silicon film, a metal film, a metal nitride film, or a multi-layered structure of those films. The metal film may be a titanium film, a titanium nitride film, or a tungsten film. If the conductive plug 69 may be formed of the metal film, the metal nitride film or the multi-layered structure of those films, a metal silicide film is formed on the interface between the contact plug 58 and the conductive plug 69. The top surface of the conductive plug 69 is leveled to the top surface of the interlayer insulator 66.

A conductive plug pad 70 is formed over the conductive plug 69 and the interlayer insulator 66 so that the conductive plug pad 70 contacts with a part of the top surface of the conductive plug 69. The conductive plug pad 70 may be made of a conductive material that is similar to or the same as the conductive material of the conductive plug 69. The center of the conductive plug pad 70 is misaligned from the center of the conductive plug 69.

A chemical vapor deposition process is carried out to form a silicon nitride film 71 which covers the conductive plug pad 70, the conductive plug 69 and the interlayer insulator 66. A further chemical vapor deposition process is carried out to form an interlayer insulator 72 which covers the silicon nitride film 71.

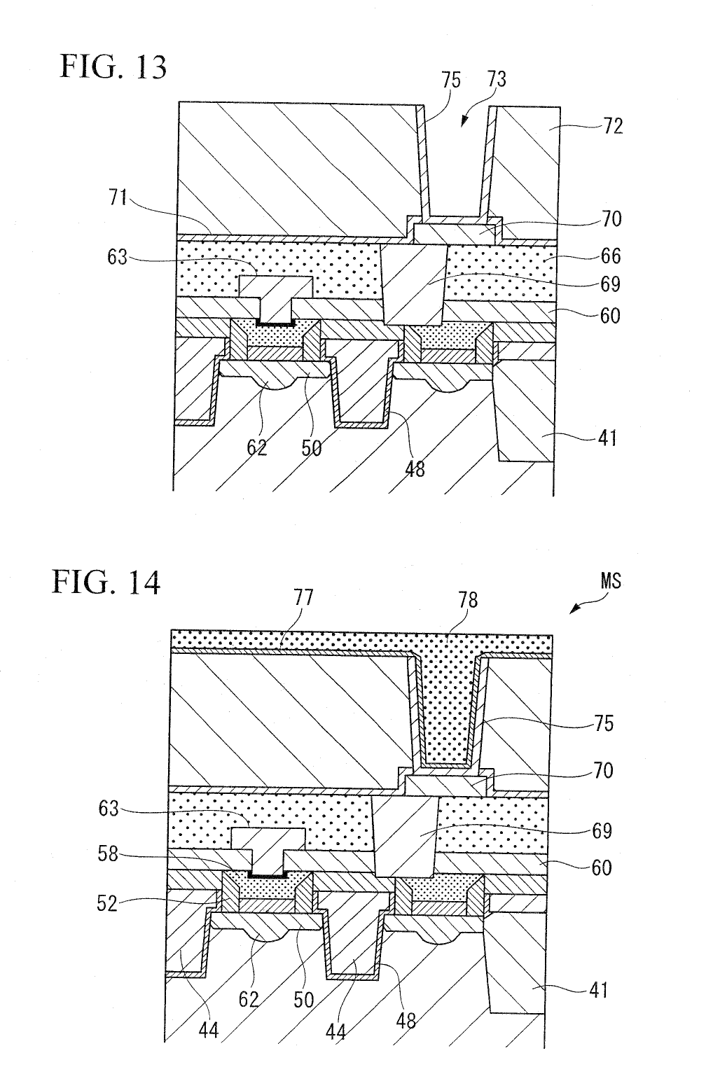

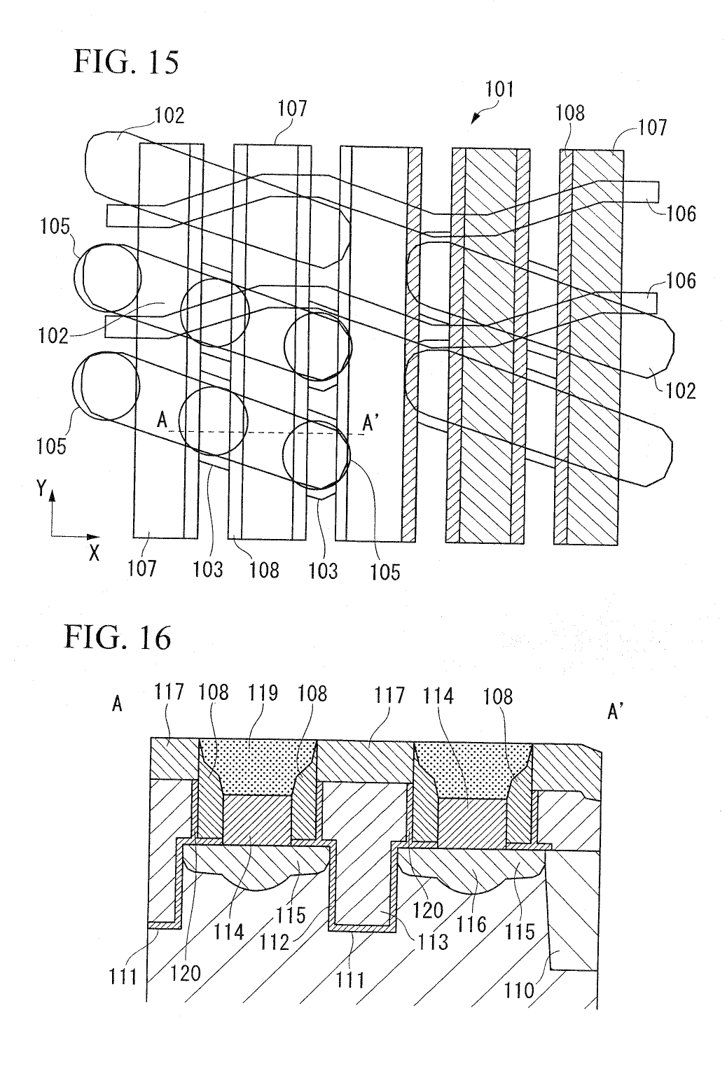

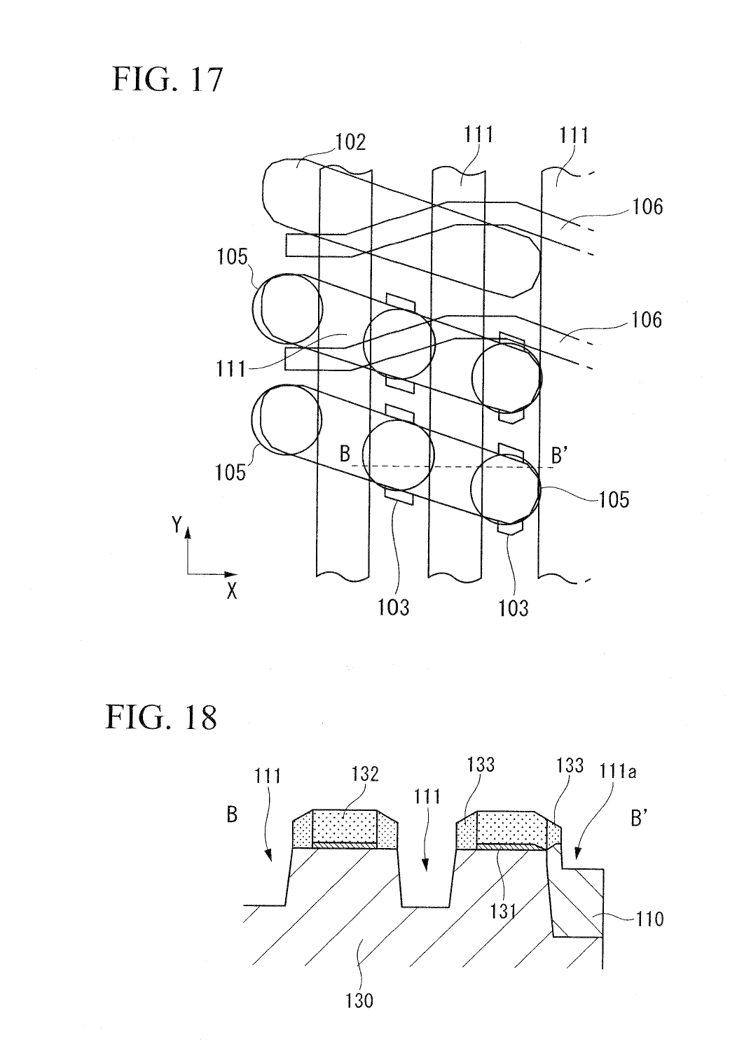

As shown in FIG. 13, a contact hole 73 is formed in the interlayer insulator 72 and the silicon nitride film 71, so that a part of the top surface of the conductive plug pad 70 is shown under the contact hole 73. The center of the contact hole 73 is almost or just aligned to the center of the conductive plug pad 70. A bottom electrode 75 of a capacitor is formed which covers inner walls of the contact hole 73 and also the exposed part of the top surface of the conductive plug pad 70. Namely, the bottom electrode 75 contacts with the conductive plug pad 70. The bottom electrode 75 may be formed by a chemical vapor deposition process. Typical examples of the bottom electrode 75 may include, but are not limited to, a silicon film, a metal film, a metal nitride film, and a multi-layered structure of those films. Typical examples of the metal film may include, but are not limited to, a tungsten (W) film, a titanium (Ti) film, a platinum (Pt) film, and a ruthenium (Ru) film. A conductive film is formed which covers the top surface and inner wall of the interlayer insulator 72 and the exposed surface of the conductive plug pad 70. The conductive film is selectively removed to leave the conductive film only within the contact hole 73. The conductive film can be selectively removed by an anisotropic dry etching process or a chemical mechanical polishing process. The anisotropic dry etching process can be realized by a reactive ion etching process.

As shown in FIG. 14, a capacitive insulating film 77 is formed which covers the bottom electrode 75 and the top surface of the interlayer insulator 72. Typical examples of the capacitive insulating film 77 may include, but are not limited to, a tantalum oxide film, an aluminum oxide film, a hafnium oxide film, a zirconium oxide film, stacks thereof, or a film of mixture of those compounds. A top electrode 78 is formed on the capacitive insulating film 77 so that the top electrode 78 fills up the contact hole 73 and extends over the interlayer insulator 72. Typical examples of the top electrode 78 may include, but are not limited to, a metal film, a metal nitride film, and a stack thereof. Typical examples of the metal film may include, but are not limited to, a tungsten film, a titanium film, a platinum film, and a ruthenium film. As a result, a memory cell MS is formed which includes trench gate transistors and a capacitor. As described with reference to FIGS. 1 and 2, the trench gate transistors have superior performances.

As used herein, the following directional terms “forward, rearward, above, downward, vertical, horizontal, below, and transverse” as well as any other similar directional terms refer to those directions of a device of the present invention. Accordingly, these terms, as utilized to describe the present invention should be interpreted relative to a device of the present invention.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor device comprising:
a semiconductor substrate including a first array of separate grooves, a second array of separate active regions, and at least an isolating region, the isolating region separating the separate active regions from each other, each separate groove extending in the separate active region and not extending over the isolating region; and
a third array of semiconductor elements, each of which has an electrically conductive portion that is provided in the separate groove.

2. The semiconductor device according to claim 1, wherein the semiconductor element is a trench gate transistor, and the electrically conductive portion is a gate electrode.

3. The semiconductor device according to claim 2, wherein the trench gate transistor includes:
a gate insulating film which covers an inner wall of the separate groove;
the gate electrode which is provided on the gate insulating film in the separate groove; and
source and drain regions in the semiconductor substrate, the source and drain regions being separated from each other by the separate groove.

4. The semiconductor device according to claim 2, wherein the isolating region comprises a trench isolation film, one or more trench gate transistors are provided in each separate active region, and the separate groove is positioned corresponding to a channel region of each trench gate transistor.

5. The semiconductor device according to claim 2, wherein the isolating region comprises a trench isolation film, one or more trench gate transistors are provided in each separate active region, and the separate groove is limited only in an interposed region between source and drain regions of each trench gate transistor.

6. The semiconductor device according to claim 2, wherein the isolating region comprises a trench isolation film, and the separate active regions are separated by the trench isolation film, each separate active region has at least one trench gate transistor, the separate groove is positioned corresponding to a channel region of each trench gate transistor, and the separate groove does not overlap the trench isolation film at an intermediate position between the separate active regions.

7. A method of forming a semiconductor device, the method comprising:
preparing a semiconductor substrate that includes a first array of separate grooves, a second array of separate active regions, and at least an isolating region, the isolating region separating the separate active regions from each other, each separate groove extending in the separate active region and not extending over the isolating region; and
forming a third array of semiconductor elements on the semiconductor substrate, each of which has an electrically conductive portion that is provided in the separate groove.

8. The method according to claim 7, wherein the semiconductor element is a trench gate transistor, and the electrically conductive portion is a gate electrode.

9. The method according to claim 8, wherein forming the trench gate transistor comprises:
forming a gate insulating film which covers an inner wall of the separate groove;
forming the gate electrode on the gate insulating film in the separate groove; and
forming source and drain regions in the semiconductor substrate, the source and drain regions being separated from each other by the separate groove.

10. The method according to claim 8, wherein the isolating region comprises a trench isolation film, one or more trench gate transistors are formed in each separate active region, and the separate groove is formed at a position which corresponds to a channel region of each trench gate transistor.

11. The method according to claim 8, wherein the isolating region comprises a trench isolation film, one or more trench gate transistors are formed in each separate active region, and the separate groove is formed only in an interposed region between source and drain regions of each trench gate transistor.

12. The method according to claim 8, wherein the isolating region comprises a trench isolation film, and the separate active regions are formed to be separated by the trench isolation film, each separate active region is formed to have at least one trench gate transistor, the separate groove is formed at a position which corresponds to a channel region of each trench gate transistor, and the separate groove is formed, which does not overlap the trench isolation film at an intermediate position between the separate active regions.

13. The method according to claim 8, further comprising:
carrying out a baking process in a hydrogen atmosphere after the separate grooves are formed.

14. The method according to claim 13, wherein the semiconductor substrate is a silicon substrate, the baking process is carried out to cause silicon atoms to move, thereby reducing surface-irregularly on the opening edge of each separate groove.
